(19) United States
(12) Patent Application Publication
(10) Pub. No.: US 2024/0091878 A1
(43) Pub. Date: Mar. 21, 2024

(54) METHOD OF RUNNING A LASER SYSTEM, LASER SYSTEM AND EVAPORATION SYSTEM

(71) Applicant: MAX-PLANCK-GESELLSCHAFT ZUR FÖRDERUNG DER WISSENSCHAFTEN E.V., München (DE)

(72) Inventor: Wolfgang BRAUN, Bietigheim-Bissingen (DE)

(21) Appl. No.: 18/274,431

(22) PCT Filed: Jan. 27, 2021
(86) PCT No.: PCT/EP2021/051882

§ 371 Date: Jul. 26, 2023

(51) Int. Cl. B23K 26/06; B23K 26/073; B23K 26/36; B23K 26/70

(52) U.S. Cl. CPC B23K 26/0626; B23K 26/0643; B23K 26/0648; B23K 26/073; B23K 26/36; B23K 26/707

(57) ABSTRACT

The present invention is related to a method for running a laser system (10) for providing a laser beam (22) for heating a surface (68) of a target (66) located in a reaction chamber (62) of an evaporation system (60), the laser system (10) comprising a laser light source (20) for providing an at least essentially parallel laser beam (22) with an at least essentially centrally peaked intensity profile (24). In addition, the present invention is related to a laser system (10) for heating a surface (68) of a target (66) located in a reaction chamber (62) of an evaporation system (60), the reaction chamber (62) comprising a chamber window (64), and the laser system (10) comprising a laser light source (20) for providing an at least essentially parallel laser beam (22) with an at least essentially centrally peaked intensity profile (24). Further, the present invention is related to an evaporation system (60) the evaporation system (60) comprising a target (66) located in a reaction chamber (62) and at least one laser system (10) for heating a surface (68) of the target (66).

The present invention is related to a method of running a laser system for providing a laser beam capable of heating a surface of a target located in a reaction chamber of an evaporation system, the laser system comprising a laser light source for providing an at least essentially parallel laser beam with an at least essentially uniform intensity profile. In addition, the present invention is related to a laser system for heating a surface of a target located in the reaction chamber of an evaporation system, the reaction chamber comprising a chamber window, and the laser system comprising a laser light source for providing an at least essentially parallel laser beam with an at least essentially uniform intensity profile. Further, the present invention is related to an evaporation system, the evaporation system comprising a target located in a reaction chamber and at least one laser system for heating a surface of the target.

In evaporation systems and similar applications, the surfaces of bodies containing solid and/or liquid material can be heated in particular in a vacuum environment by means of laser radiation. Such heating is known for instance in the context of epitaxy techniques such as molecular beam epitaxy (MBE) and is generally similar in laser applications such as welding or cutting. In most applications uniform heating of the heated surface is desirable. To achieve uniform heating of the irradiated surface, beam shaping to achieve a top-hat profile, mainly using wave optics elements, has been implemented for ensuring a uniform energy deposition by the laser radiation.

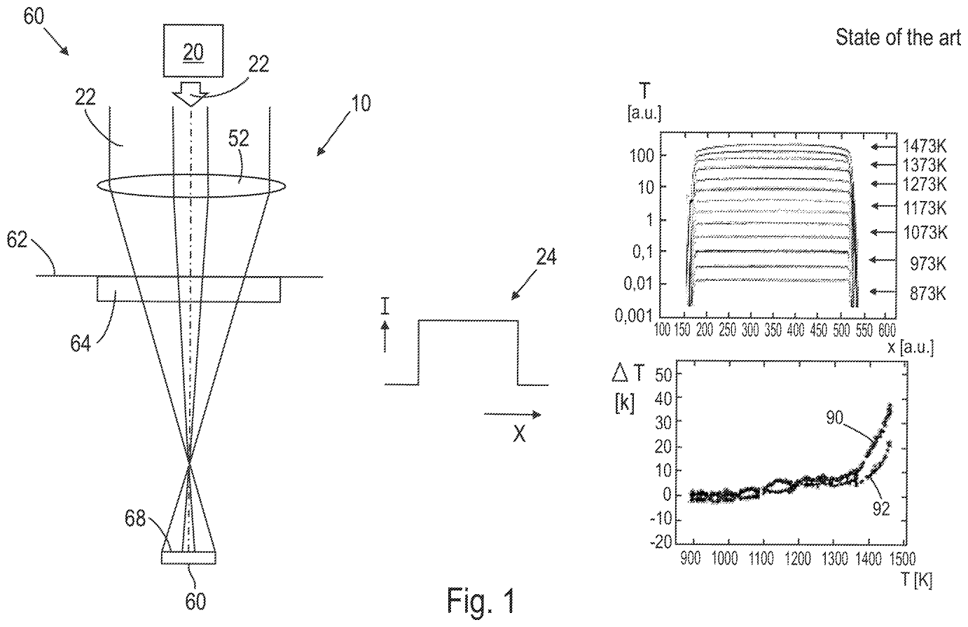

A possible embodiment of an evaporation system 60 mentioned above and equipped with a laser system 10 according to the state-of-the-art is shown on the left-hand side image in FIG. 1. The laser light source 20 of the laser system 10 provides a laser beam 22 with a uniform top-hat intensity profile 24 as shown in the middle image of FIG. 1. A focusing element 52 focuses the laser beam 22 through a chamber window 64 into a reaction chamber 62 of the evaporation system 60 onto the surface 68 of the target 66 to be heated.

However, at the higher powers and therefore higher temperatures of the heated material, flat intensity profiles 24 impinging with a constant power density onto the irradiated surface 68 no longer produce a uniform temperature across the irradiated surface 68. This is shown on the right-hand-side image of FIG. 1, where the upper graph shows measured intensities and converted temperatures against the respective position on the surface 68 of the target 66 for different temperatures ranging from 873 K to 1473 K, the lower graph shows the actual deviation of the temperature of the surface 68 towards the left 90 and right 92 edge of the target 66 versus the overall temperature of the surface 68. It is clearly visible that with rising temperature the deviations 90, 92 get more and more severe.

In view of the above, it is an object of the present invention to provide an improved method of running a laser system, an improved laser system and an improved evaporation system which do not have the aforementioned drawbacks of the state-of-the-art. In particular it is an object of the present invention to provide a method of running a laser system, a laser system and an evaporation system which allow heating of a surface of a target in a uniform way with respect to the resulting temperature on the surface of the target, in particular for different target values of temperatures of the surface of the target, preferably for a continuously changing target value of the temperature of the surface of the target.

This object is satisfied by the respective independent patent claims. In particular, this object is satisfied by a method of running a laser system for providing a laser beam capable of heating a surface of a target according to claim 1, by a laser system for heating a surface of a target according to claim 6 and by an evaporation system according to claim 33. The dependent claims describe preferred embodiments of the invention. Details and advantages described with respect to a method of running a laser system according to the first aspect of the invention also refer to a laser system according to the second aspect of the invention and to an evaporation system according to the third aspect of the invention and vice versa, if of technical sense.

According to the first aspect of the invention, the object is satisfied by a method of running a laser system for providing a laser beam capable of heating a surface of a target located in a reaction chamber of an evaporation system, the laser system comprising a laser light source for providing an at least essentially parallel laser beam with an at least essentially centrally peaked intensity profile. The method according to the present invention comprises the steps of:
a) Determining a temperature information of the surface of the target,
b) Determining an adapted intensity profile for the laser beam with a lower center intensity based on the temperature information determined in step a),
c) Shaping the intensity profile of the laser beam based on the determination carried out in step b), and
d) Providing the laser beam with the adapted intensity profile shaped in step c) for heating the surface of the target located in the reaction chamber of the evaporation system.

The method according to the present invention can be for instance for thermal evaporation and/or sublimation of one or more target materials. As an alternative, also heating of the surface of a target to be coated with evaporated and/or sublimated material is possible. The respective target is located in the reaction chamber of an evaporation system, wherein the reaction chamber can contain a suitable reaction atmosphere and/or is evacuated. The laser light of the laser light source is coupled into the reaction chamber, impinges on the surface of the target, and the laser energy absorbed by the target results in the desired heating of the surface of the target.

However, as described above, in most of the cases heating the target surface with a laser beam comprising an at least essentially centrally peaked intensity profile, in particular with a high intensity laser beam and hence high temperatures of the target surface, leads to a non-uniform temperature distribution on the surface of the target. Centrally peaked intensity profiles according to the present invention encompasses for instance Gaussian distributions and other singly peaked distributions decaying, preferably monotonously decaying, in the radial direction away from the optical and/or symmetry axis. Uniform distributions are also identified as singly peaked profiles according to the present invention. In particular, radiation losses, which are significantly higher towards the outer rim of the target surface for instance due to the presence of side faces of the target, lead to a lower temperature of the target surface towards the outer rim of the target. As the radiation losses are proportional to T⁴, the temperature difference very quickly gets more and more severe with rising temperature.

To compensate this effect, in the first step a) of the method according to the present invention, a temperature information of the surface of the target is determined. Beside to actual temperature measurements, said determination of the temperature alternatively or additionally also comprises a determination of the intensity of the laser light and deriving the temperature information therefrom, for instance by using physical and/or empirical models of the target, previously prepared calculations and/or simulations. In particular, determining the temperature information allows identifying a decrease of temperature from its highest value at and/or near the center of the surface of the target towards the outer rim and/or edges and/or corners of the surface of the target, in other words to identify a temperature profile and a temperature gradient, respectively.

Hence, after step a), the temperature information about the presence of the respective temperatures at the surface of the target, in particular in its center and at its outer rim, respectively, is available. Said temperature information can include a precise mapping of the profile of the surface temperature. Additionally, or alternatively, also only at least one relative difference of temperatures at and/or near the center and at the outer rim of the surface of the target can form said temperature information according to the present invention. Another example of said temperature information according to the present invention is an estimation of the expected temperatures, based on the initial laser intensity provided by the laser light source and an exposure time, and/or based on physical and/or empirical models, previously prepared calculations, and/or simulations.

Based on said temperature information present after step a) of the method according to the present invention, in the next step b) an intensity profile is determined. For compensating the aforementioned effects leading to the temperature profile at the surface of the target, in particular the higher radiation losses towards the outer rim of the surface of the target, said adapted intensity profile comprises a lower intensity at its center, and a higher intensity towards its outer rim, and/or edges, respectively. In other words, the adapted intensity profile provides laser light with a higher intensity for regions of the surface of the target with lower temperature. This allows compensating the effects mentioned above at least partly, and a more uniform temperature of the surface of the target can be achieved.

The next two steps c) and d) of the method according to the present invention comprise the actual provision of the laser light with the adapted intensity profile determined in step b) onto the surface of the target.

In step c), the at least essentially uniform intensity profile of the laser beam provided by the laser light source is accordingly shaped to the adapted intensity profile determined in step b). Said shaping can be for instance carried out by a suitable beam shaping system comprising corresponding optical and/or shaping elements like lenses, mirrors or the like. After step c), the initial and at least essentially uniform intensity profile of the laser beam is replaced by the adapted intensity profile determined in step b).

The last step d) of the method according to the present invention includes the actual provision of the laser beam with the adapted intensity profile onto the surface of the target. The laser beam is coupled into the reaction chamber of the evaporation system and directed to the surface of the target. As the intensity profile of the laser beam is accordingly adapted, in particular higher radiation losses at the edges of the target can be compensated and a uniform temperature profile of the surface of the target can be achieved.

Further, the method according to the present invention can comprise that the determining of the temperature information in step a) includes at least one of the following:
Estimating the temperature information based on the intensity of the laser beam provided by the laser light source,
Estimating the temperature information based on measuring the temperature at the center of the surface of the target,
Estimating the temperature information based on measuring the temperature at the outer rim of the surface of the target, and/or
Estimating the temperature information based on measuring the temperature at the center, at the outer rim, and at least at one additional position of the surface of the target.

This list of possible determination methods for the temperature information is not completed, and also other determination methods can be implemented if technically possible and reasonable. In particular, for the actual implementation of the method according to the present invention, the most appropriate determination method can be chosen, for instance considering available sensors, computing power and/or building space.

Further, the method according to the present invention can comprise that the respective temperature of the surface of the target is measured with respect to the provided laser beam at the far side of the target opposite to the surface of the target heated by the laser beam.

The heating of the target by the laser beam is in most of the applications sufficient for providing a heating of the target as a whole and not only of the surface directly heated by the impinging laser beam. Further, in some applications of the method according to the present invention, the target is heated on one side, wherein a uniform heating of the far side of the target opposite to the surface of the target directly heated by the laser beam is the decisive object to be achieved. Hence measuring the respective temperature at and of, respectively, the far side of the target is a suitable possibility, especially as a required sensor element can be placed without interference with the impinging laser beam.

Additionally or alternatively, the method according to the present invention can also comprise that the respective temperature of the surface of the target is measured on-axis with the provided laser beam.

Preferably, this embodiment can be implemented with a laser system comprising a distributed Bragg reflector tuned for the wavelength of the laser beam different to the wavelength of the heat radiation originating from the heated surface of the target. Hence, a suitable sensor element arranged at the far side of the distributed Bragg reflector on-axis with respect to the laser beam directed towards the target on the one hand is shielded against the laser light by the distributed Bragg reflector, whereby on the other hand the distributed Bragg reflector is at least partially transparent for the heat radiation emitted by the surface of the target. Hence a direct measurement of the respective temperature of the heated surface of the target is also suitable.

For all temperature measurements described above, preferably also temporal and/or spatial temperature variations can be measured.

In addition, the method according to the present invention can be characterized in that the newly shaped intensity profile is rotationally symmetric. As also the intensity profile of the laser beam initially provided by the laser light source is rotationally symmetric in most of the cases, it is preferable to also provide the adapted intensity profile with this respectively rotational symmetry. Further, such a rotationally symmetric intensity profile is preserved at a reflection of the respective laser beam on a flat or appropriately shaped other mirror at an incidence angle of 45°. Hence, the path of the laser beam can be easily adjusted without disturbing and/or destroying said rotational symmetry.

According to the second aspect of the invention, the object is satisfied by a laser system for heating a surface of a target located in a reaction chamber of an evaporation system, the reaction chamber comprising a chamber window, and the laser system comprising a laser light source for providing an at least essentially parallel laser beam with an at least essentially centrally peaked intensity profile. The laser system according to the present invention is characterized in that the laser system comprises a beam shaping system configured to carry out at least step c) and optionally step d) of the method according to the first aspect of the present invention.

The laser system according to the second aspect of the present invention is configured to carry out at least step c), and optionally step d), of the method according to the first aspect of the present invention. In said step c), the intensity profile of the laser beam is accordingly shaped for compensating the temperature profile of the surface of the heated target. Said step d) encompasses the actual provision of the adaptively shaped laser beam onto the target. Hence, all features and advantages described above with respect to a method according to the first aspect of the invention, at least with respect to steps c) and optionally d), can also be provided by the laser system according to the second aspect of the invention used for carrying out the method according to the first aspect of the invention.

Preferably, the laser system according to the present invention can be characterized in that the beam shaping system comprises, along the path of the laser beam at least the following shaping elements:
a beam telescope for adjusting a diameter of the laser beam;
a generalized first axicon for transforming the parallel laser beam into a diverging laser beam with an at least partly ring-shaped intensity profile;
an optical assembly comprising as shaping elements a clipping aperture with a clipping aperture opening for clipping outer parts of the ring-shaped intensity profile of the laser beam and a generalized second axicon for compensating the divergence of the laser beam and transforming the divergent laser beam into a parallel laser beam; and
a focusing element for focusing the laser beam towards the surface of the target.

Likewise to the method described above, also laser systems according to the invention can be used for instance for thermal evaporation and/or sublimation of one or more target materials. As an alternative, also heating of the surface of a target to be coated with evaporated and/or sublimated material is possible. The respective target is located in the reaction chamber of an evaporation system, wherein the reaction chamber can contain a suitable reaction atmosphere and/or is evacuated. For coupling the laser light of the laser light source into the reaction chamber, the reaction chamber comprises a chamber window.

It has been found that the aforementioned temperature drop towards the edges of the target is due to the fact that at higher temperatures a substantial amount of heat is lost through radiation according to Planck's law, from the front and back surfaces of the sample, but also additionally through its sides. This leads to a lateral heat flow from the center to the rim, and a corresponding temperature gradient along this radial direction. The sample becomes hotter at the center, and colder at the rim. The laser system according to the present invention is constructed to compensate these higher radiation losses at the outer rim sides of the target.

The aforementioned laser light source provides a beam of laser light. This laser light is coherent and at least essentially parallel, in particular very close to completely parallel. In addition, the laser light comprises an at least essentially uniform intensity profile, in particular a completely uniform intensity profile. In other words, the laser light provided by the laser light source preferably comprises an ideal parallel top-hat intensity profile.

The laser light provided by the laser light source is subsequently modified by the beam shaping system of the laser system according to the present invention. Generally, all elements of the beam shaping system are aligned with respect to an axis of the laser beam and hence to the general propagation direction of the laser beam.

Along the path of the laser beam, the first element of the beam shaping system is the beam telescope. This beam telescope is used to adjust the diameter of the laser beam. The at least essential parallel alignment of the laser beam is conserved by the beam telescope. In particular, the beam telescope preferably allows choosing the suitable diameter needed for the actual intensity profile to be realized at the target. The influence of the diameter on the intensity profile will be discussed in the following.

The two main elements of the beam shaping system of the laser system according to the present invention are the first generalized axicon and the second generalized axicon. These generalized axicons can be formed for instance as strictly axicons, i.e. as purely conical lenses. A generalized axicon according to the present invention comprises the features of a strictly axicon. However, small and controlled deviations from the pure conical form allow optimizing the resulting intensity profile provided after the generalized axicons. Preferably, the generalized axicons can be provided as freeform elements. In the following, all mentioned axicons are such generalized axicons, even if not explicitly noted.

The first generalized axicon transfers the parallel laser beam into a diverging laser beam with an at least partly ring-shaped intensity profile. In other words, after the first axicon the laser light preferably forms a truncated light cone opening up after the first axicon and having an intensity profile which is higher towards the rim of the cone and lower towards the center of the cone. Preferably, the intensity is shifted only partly towards the rim of the said light cone and the intensity towards the center of the light cone is not zero. Preferably, the intensity towards the center of the light cone stays high enough for ensuring the desired heating throughout the target surface.

After the first axicon, an optical assembly is arranged comprising as shaping elements a the second generalized axicon and a clipping aperture.

The second axicon is used to compensate the divergence induced by the first axicon into the laser beam and hence for re-transforming the laser beam back into a parallel laser beam. For this purpose, a focal length of the second axicon is preferably matched, in particular equal, to a focal length of the first axicon. Additionally, if the two axicons are formed as conical lenses, the conical shape of the axicons can preferably be complementary in the sense that their cone angles are of the same size but of different signs. In summary, after the second axicon the laser beam is again at least essentially parallel, but now comprises an intensity profile which is higher towards its edge.

The ring part of the ring-shaped intensity profile provided by the first axicon, the ring part particularly resembling a torus, can essentially be described by two characteristic lengths, the width of the ring itself and the radius of the ring with respect to the center of the torus. The radius is defined by the divergence induced by the first axicon and the distance between the first and second axicon.

As mentioned above, the first and second generalized axicon preferably are conical lenses. Preferably, the pair of axicons are unchanging and static. In this case, also these variables, and therefore also said radius of the ring of the ring-shaped intensity profile, are fixed. In contrast to that, the width of the ring directly depends on the size of the beam spot of the laser beam impinging on the first axicon. In other words, the width of the ring of the ring-shaped intensity profile depends on the beam diameter which can, as described above, be actively adjusted by the beam telescope. Hence, adjusting the diameter of the laser beam by the beam telescope allows adjusting the actual embodiment of the shape of the ring-shaped intensity profile impinging on the target. As extreme values, on the one hand an essentially a top-hat intensity profile, (the width of the ring is much larger, in particular at least four times larger, than the radius of the ring) and on the other hand an essentially torus shaped intensity profile (the width of the ring is much smaller than the radius of the ring) can be achieved.

The clipping aperture forms the other shaping element provided by the optical assembly. The clipping aperture comprises a clipping aperture opening, preferably both perpendicularly aligned with and symmetrical to the general propagation direction of the laser beam, respectively.

The clipping aperture clips outer parts of the ring-shaped intensity profile of the laser beam and hence defines the outer edge of the laser beam. In addition to defining the final diameter of the laser beam provided by the laser system, the clipping aperture can also define the actual shape of the intensity distribution, in particular towards the edge of the intensity distribution, as clipping the torus part of the ring-shaped intensity profile at different radii with respect to the center of the laser beam can result in different shapes of the final intensity distribution.

A focusing element forms the last element of the beam shaping system along the path of the laser beam of the laser system according to the present invention. This focusing element allows focusing the laser light with its now ring-shaped intensity profile towards the target. In particular, the focusing element, and hence its focal length and therefore the position of its focal point, can be chosen for instance depending on a size of the target, a distance between the focusing element and the target and/or a diameter of the laser beam after the second axicon. In summary, the focusing element can for instance ensure a complete and/or partially illumination of the surface of the target by the laser beam provided by the laser system according to the present invention.

In summary, the laser system according to the present invention can provide a laser beam for heating a surface of a target of an evaporation system. In particular, the provided laser beam comprises an actively adjustable intensity profile which is ring-shaped and comprises higher intensity values towards its outer edges. Especially at higher temperatures of the heated target, this allows compensating higher radiation losses at the outer parts of the surface of the target and hence a uniform heating of the surface of the target resulting in a spatially constant or at least essentially constant surface temperature of the target heated by the laser system according to the present invention.

Further, the laser system according to the present invention can be characterized in that within the optical assembly the clipping aperture is arranged upstream of the second axicon along the path of the laser beam. In other words, the clipping aperture is arranged between the pair of axicons. As the laser beam is divergent after the first axicon, the position of the clipping aperture after the first axicon and hence the distance between these elements defines the outer cutoff of the laser beam. Therefore, choosing or actively adjusting said position of the clipping aperture also influences the actual intensity profile providable at the surface of the target as the cutoff impressed by the clipping aperture actually defines the diameter and/or the actual intensity profile of the parallel laser beam provided after the second axicon.

Alternatively, the laser system according to the present invention can comprise that within the optical assembly the second axicon is arranged upstream of the clipping aperture along the path of the laser beam. Different to the embodiment described above, in this embodiment the clipping aperture is arranged after the second axicon and hence at a position with a parallel laser beam. Accordingly, the actual position of the arrangement of the clipping aperture is less crucial for the provided intensity distribution. A setup of this embodiment of the laser system according to the present invention can therefore be simplified.

In addition, the laser system according to the present invention can be enhanced by that at least two consecutively arranged shaping elements of the beam shaping system are integrated into a combined shaping element. By integrating two consecutively arranged shaping elements of the beam shaping system into a single shaping element, the number of shaping elements of the beam shaping system can be reduced. As a result, a reduction of installation space requirements and overall complexity of the beam shaping system can be provided.

Further, the laser system according to the invention can be characterized in that at least some parts of the beam shaping system are arranged outside of the chamber window of the reaction chamber. Within the reaction chamber, a reaction atmosphere suitable for the planned evaporation reaction is contained. This reaction atmosphere can for instance be a high or even ultra-high vacuum up to 10⁻⁹ mbar or even lower. Alternatively, also actual atmospheres comprising reactive gases, for instance ozone, are possible as a reaction atmosphere according to the present invention.

For maintaining the reaction atmosphere, undesired interactions of the reaction atmosphere with elements within the reaction chamber have to be avoided. By arranging at least some parts of the beam shaping system outside of the chamber window of the reaction chamber, the aforementioned avoidance of interactions can be provided more easily, as for each part of the beam shaping system outside of the chamber an interaction with the reaction atmosphere within the reaction chamber is automatically prohibited.

Preferably, the laser system according to the present invention is further enhanced thereby that said parts comprise at least some or all of the following components: the beam telescope, the first generalized axicon, the optical assembly, the clipping aperture, and the second generalized axicon. Each of the listed parts provides an important part of the beam shaping process. The beam telescope defines the diameter of the laser beam, the first and second generalized axicon provide the ring-shaped intensity profile, and the clipping aperture provides the spatial position of the outer edge of the laser beam. The optical assembly comprises both the clipping aperture and the second axicon, respectively. In addition to the aforementioned advantage of avoidance of interaction with the reaction atmosphere, arranging said parts outside of the reaction chamber also allows an easy access to these parts, for instance for adjustments and/or replacements.

In addition, the laser system according to the present invention can also be characterized in that the focusing element is arranged outside of the chamber window of the reaction chamber. As the focusing element forms the last element of the beam shaping system along the path of the laser beam, in this preferred embodiment of the laser system according to the present invention the complete beam shaping system is fully arranged outside of the chamber window of the reaction chamber. Hence, interactions of the beam shaping system with the reaction atmosphere within the reaction chamber can therefore be avoided for all parts of the beam shaping system. Further, also an easy access can be provided to all components of the beam shaping system.

Preferably, the laser system according to the present invention can be enhanced further by that the second axicon and the focusing element are integrated into a freeform lens or a freeform mirror. By integrating these two parts of the beam shaping system into a single optical element, the number of optical elements of the beam shaping system can be reduced. As a result, a reduction of installation space requirements and overall complexity of the beam shaping system can be provided.

Additionally, in a preferred embodiment of the laser system according to the present invention, the freeform mirror is an adaptive mirror with an actively adjustable focal length. As mentioned above, the freeform mirror provides the functions both of the second axicon and of the focusing element, respectively. An actively adjustable focal length is a function assigned to the focusing element and allows to adapt the beam shaping system to at least two, several, or even a continuum of different working distances to the target to be heated within the reaction chamber. Additionally, by adjusting the focal length, also the illumination of the target to be heated can be adjusted.

Alternatively, the laser system according to the present invention can be characterized in that the focusing element is arranged within the reaction chamber after the chamber window. The energy density of the laser beam is coupled to the area of a cross section of the laser beam and naturally is lower for larger diameters of the laser beam. Hence, in particular for high heating powers it can be of advantage to provide the laser beam with a diameter as large as possible while passing the chamber window for minimizing an energy deposition into the chamber window. Said maximization of the illuminated area of the chamber window can be achieved by arranging the focusing element inside of the reaction chamber, as the focusing element focuses the laser beam onto the surface of the target and thereby naturally reduces the diameter of the laser beam. Preferably, all other parts of the beam shaping system up to the second axicon are arranged outside of the chamber window of the reaction chamber for providing the aforementioned advantages of maintaining the reaction atmosphere and accessibility of the elements of the beam shaping system.

In another preferred embodiment of the laser system according to the present invention, the beam telescope comprises optical elements for a continuous adjustment of the diameter of the laser beam. As mentioned above, the beam diameter adjusted by the beam telescope essentially defines properties of the ring-shaped intensity profile provided by the pair of axicons and the clipping aperture. In particular, in an embodiment of the beam shaping system with fixed first axicon, second axicon, and clipping aperture, the beam telescope solely defines the adjustments possible for the properties of the provided intensity profile. By implementing optical elements for a continuous adjustment of said beam diameter of the laser beam, also the adjustment of the resulting properties of the provided ring-shaped intensity profile can be provided in a continuous way. An especially good adaptation of the intensity profile provided by the beam shaping system of the laser system according to the present invention to the actual heating needs can thereby be provided.

Further, the laser system according to the present invention can comprise that the optical elements of the beam telescope comprise along the path of the laser beam a matched pair of a focusing optical element and a defocusing optical element.

In other words, within the beam telescope at first the laser beam is focused and hence the diameter of the laser beam gets smaller after the focusing optical element. The subsequently arranged defocusing element receives this converging laser beam and transfers it back into an essentially parallel laser beam. For this, the focusing optical element and the defocusing optical element form a matched pair in the sense of that the focusing of the laser beam provided by the focusing optical element, the defocusing of the laser beam provided by the defocusing element, and their relative positions are chosen such that the properties of the optical elements compensate each other. In summary, after the defocusing optical element of the beam telescope a parallel laser beam with a reduced diameter can be provided.

Further, a distance between the focusing optical element and the defocusing optical element is preferably chosen such that the focal point position of the focusing optical element falls outside of this distance. A focal volume, in which the laser intensity would reach its highest values, and hence a possible hazard source, can thereby be avoided.

Alternatively, the laser system according to the present invention can comprise that the optical elements of the beam telescope comprise along the path of the laser beam a matched pair of a defocusing optical element and a focusing optical element.

In other words, within the beam telescope at first the laser beam is defocused and hence the diameter of the laser beam gets larger after the defocusing optical element. The subsequently arranged focusing element receives this diverging laser beam and transfers it back into an essentially parallel laser beam. For this, the defocusing optical element and the focusing optical element form a matched pair in the sense of that the defocusing of the laser beam provided by the defocusing optical element, the focusing of the laser beam provided by the focusing element, and their relative positions are chosen such that the properties of the optical elements compensate each other. In summary, after the focusing optical element of the beam telescope a parallel laser beam with an enlarged diameter can be provided.

The laser system according to the present invention can be further enhanced by that the pair of optical elements are matched such that the pair of optical elements comprise respective positions along the path of the laser beam and respective focal lengths for providing at least essentially identical, preferably completely identical, respective focal point positions of the pair of optical elements.

In other words, the respective positions of the focal points of the focusing optical element and of the defocusing optical element, respectively, fall onto each other or are at least arranged in the immediate vicinity of each other. Independent of the order of the two optical elements, this matching of the positions of the respective focal points provides that the focusing and defocusing characteristics of the optical elements are matched and compensate each other. Thereby preserving the parallel alignment of the laser beam can be ensured during adjusting the diameter of the laser beam especially easily.

Preferably, the laser system according to the present invention can be further enhanced by that the respective focal lengths of the optical elements along the path of the laser beam can be continuously adjusted.

As mentioned above, the respective focal lengths of the optical elements are matched such that the positions of the respective focal points are at least essentially identical, preferably completely identical. By continuously adjusting these focal lengths, and simultaneously preserving their matching during the adjustment, also the size of the diameter of the laser beam at the second optical element of the matched pair of optical elements can be continuously adjusted. Hence, by continuously adjusting said respective focal lengths also a continuous adjustment of the diameter of the parallel laser beam after the second optical element and hence after the beam telescope can be provided. As described above, this results in a continuous variation of the ring-shaped intensity profile of the laser beam provided by the beam shaping system of the laser system according to the present invention.

In particular, the laser system according to the present invention can be enhanced by that the optical elements of the beam telescope are a matched pair of at least essentially spherical lenses, in particular a matched pair of adaptive at least essentially spherical lenses.

As mentioned above, a matched pair according to the invention can be characterized in that the focal point positions of the two optical elements, and hence of the two at least essentially spherical lenses, are at least essentially identical, preferably completely identical.

An at least essentially spherical lens according to the present invention means that the lens surface can be approximated by a part of a sphere

Hence, the first lens focuses or defocuses, respectively, the impinging parallel laser beam in the same manner as the second lens again defocuses or focuses, respectively, the impinging focused laser beam. As the focal lengths of the two lenses are matched, this results again in a parallel laser beam after the second at least essentially spherical lens, depending on the present embodiment with a reduced or an enlarged diameter.

As the two lenses are at least essentially spherical, both the focusing and defocusing, respectively, property of the respective lens is constant over the whole spherical part of the respective lens. Hence, as long as for both at least essentially spherical lenses the diameter of the laser stays on the respective lens smaller than the diameter of the respective lens a parallel adjustment of the laser beam impinging on the first lens is preserved by the beam telescope. By providing adaptive lenses, actively adjusting said focal lengths of the lenses can be provided and hence the diameter of the laser beam can easily be altered and be actively adjusted, in particular without altering the relative positions of the two lenses

In an alternative embodiment, the laser system according to the present invention comprises the fact that the optical elements of the beam telescope are a matched pair of mirrors, in particular a matched pair of adaptive mirrors. In other words, in this alternative embodiment, the pair of matched at least essentially spherical lenses is replaced by a pair of matched mirrors.

All features described above with respect to the possible diameter adjustments of the laser beam provided by a pair of matched lenses can also be provided by a pair of matched mirrors. One of the mirrors provides focusing of the laser beam, the respective other mirror provides defocusing of the laser beam, whereas both possible orders of the two mirrors along the path of the laser beams can be implemented in embodiments of the laser system according to the present invention.

Preferably, the mirrors are adaptive mirrors. An adaptive mirror comprises a reflective surface whose shape can be actively adjusted. This allows for instance to actively adjust the focal length of the respective adaptive mirror. In particular, the focal length of the first adaptive mirror defines the size of the spot of the laser beam impinging on the second adaptive mirror. As mentioned above, the first adaptive mirror can be a focusing adaptive mirror and the second adaptive mirror can be a defocusing adaptive mirror or vice versa.

As the mirrors and hence their respective focal lengths are matched, the second mirror transfers the impinging laser beam back to a parallel laser beam.

Likewise as described above with respect to the matched pair of lenses, the expression ‘matched’ means also with respect to the pair of preferably adaptive mirrors that the focal point positions of the respective mirrors are at least essentially identical, preferably completely identical. Therefore, by providing a matched pair of mirrors, whose focal lengths are matched independent of their present value, a parallel laser beam with adjustable diameter can be provided, in particular without altering the relative positions of the two mirrors, similar as described above with respect to the pair of matched lenses. In another embodiment the laser system according to the present invention can comprise that the beam shaping system comprises a deflection element for changing the general propagation direction of the laser beam, wherein the deflection element is arranged along the path of the laser beam somewhere after the optical assembly.

After the optical assembly, in particular after the second axicon and the clipping aperture, the beam shaping of the laser beam in the beam shaping system is essentially completed. A placement of the deflection element somewhere after the optical assembly hence allows changing the general propagation direction of the laser beam already comprising the ring-shaped intensity profile provided by the beam shaping system of the laser system according to the present invention. Changing the general propagation direction of the laser beam can provide that the laser beam in the beam shaping system comprises a different general propagation direction than needed within the reaction chamber. An available construction space can therefore be used more efficiently. Further, spatial requirements for the setup of the laser system according to the present invention can be reduced.

Additionally, the laser system according to the present invention can be enhanced by that the deflection element is the last element of the beam shaping system arranged along the path of the laser beam before the chamber window. Hence, the deflection element is arranged outside of the chamber window of the reaction chamber. In other words, the deflection element forms the last optical element of the beam shaping system outside of the reaction chamber.

All elements of the beam shaping system arranged along the path of the laser beam before the deflection element are easily accessible, with all advantages already listed above.

In addition, the deflection element can preferably also be arranged after the focusing element. As the deflection element forms the last element of the beam shaping system, in this preferred embodiment of the laser system the beam shaping system is fully arranged outside of the reaction chamber.

Thereby all elements of the beam shaping system are easily accessible and an adjustment and/or maintenance work at the beam shaping system can be facilitated.

Preferably, the laser system according to the present invention comprises that the deflection element is a distributed Bragg reflector. A distributed Bragg reflector comprises an excellent reflectivity for a certain wavelength. By matching the distributed Bragg reflector to the wavelength of the laser beam, and essentially complete reflection of the impinging laser beam on the deflection element can be provided and intensity losses can be avoided or at least be minimized

In a further enhanced embodiment of the laser system according to the present invention, the laser system comprises sensor elements for measuring an amount of energy deposited into the deflection element and/or an amount of light transmitted through the deflection element during deflection of the laser beam. Both the respective amount of energy deposited into the deflection element and of light transmitted through the deflection element, respectively, is proportional to the amount of laser light actual reflected by the deflection element. Hence by measuring the amounts of energy deposited into the deflection element and/or light transmitted through the deflection element, an information about the intensity of the reflected laser beam and therefore about the intensity of the laser light impinging on the target can be provided. In particular, this measurement can be used for a closed-loop control of the heating of the target provided by the laser system according to the present invention.

Preferably, the laser system according to the present invention can be enhanced by that the sensor elements are position sensitive sensor elements for measuring the amount of energy deposited into the deflection element and/or the amount of light transmitted through the deflection element during deflection of the laser beam at two or more positions of the deflection element.

The laser system according to the present invention provides a laser beam for heating a target, wherein in particular the laser beam comprises the ring-shaped intensity profile. This non-uniform intensity profile is already present after the second generalized axicon and hence at the deflection element.

By using position sensitive sensor elements, said non-uniform shape of the intensity profile can be investigated at least partly. Preferably, the sensor elements comprise a position sensitivity with a sufficient granularity and resolution, at least for distinguishing between the center and the edge of the intensity profile, preferred for resolving further spatial details like said radius and width of the ring-shaped profile or a, in particular rotational, symmetry of the intensity distribution, for measuring the decisive regions of the intensity profile.

In addition, the laser system according to the present invention can be characterized in that the sensor elements are arranged on-axis with respect to the optical axis of the laser beam pointing to the target on the far side of the deflection element with respect to the impinging laser beam for measuring heat radiation emitted by the surface of the target.

In other words, these sensor elements are positioned and enabled for a direct measurement of the temperature of the surface of the target. Preferably, the sensors are enabled to measure also temporal and/or spatial temperature variations. The sensor elements serve to measure and control either the local or the averaged surface temperature of the target. Preferably, these sensor elements measure the temperature by a non-contact method, such as optical pyrometry.

The sensor measures the temperature of the irradiated surface on the axis of the heating laser beam. According to the invention, this can be provided by arranging the sensor on the far side of the deflection element, which is preferably provided as distributed Bragg reflector. Further, it can be preferably provided to tailor the distributed Bragg reflector, representing the last optical element outside the vacuum chamber, in such a way that, apart from having a high reflectance at the laser wavelength, it has a high transmittance in a different wavelength range separated from the heating laser wavelength. In particular, the high transmittance is chosen in a wavelength range expected for the heat radiation emitted by the surface of the target.

For instance, when using a CO₂ laser at approximately 10 μm wavelength, this preferred wavelength range is located at smaller wavelengths, however still large enough such that the emittance of the heated material is still high. Also, this wavelength range needs to lie in the range of high transmittance of the laser entrance window and the distributed Bragg mirror carrier material, e.g. for instance ZnSe.

For the case of a 10 μm heating laser, a typical such preferred wavelength range may be from 7 to 9 μm.

According to another embodiment of the invention the laser system can comprise that the focusing element comprises a focal length such that the clipping aperture opening is projected onto an outer rim and/or onto edges and/or onto corners of the surface of the target. In other words, the size of the laser beam at the position of the target within the reaction chamber is matched to a size of the surface of the target to be heated by the laser system according to the present invention. As mentioned above, the enlarged radiative losses during the heating occur at the rim, at edges and/or at corners of the target. On the other hand, the ring-shaped intensity of the laser beam is highest at the outer edge of the laser beam, wherein this outer edge of the laser beam is defined by the clipping aperture opening of the clipping aperture. By projecting the clipping aperture opening onto the outer rim and/or onto edges and/or onto corners of the surface of the target, a compensation of the enlarged radiative losses by the non-uniform intensity of the laser beam provided with the said ring-shaped intensity profile can therefore be insured at least partly, preferably completely.

Additionally, the laser system according to the invention can be characterized in that the focusing element focuses the laser beam on a point-like focal volume located within the reaction chamber between the chamber window and the target. The point-like focal volume represents the smallest extent of the laser beam and hence the highest energy density. Providing this focal volume between the chamber window and the target automatically ensures that the laser beam is divergent after the focal volume and hence the energy density decreases with increasing distance to the focal volume. If accidentally the target should be missed by the laser beam, this divergence ensures that the energy density at the impact on a chamber wall of the reaction chamber is low enough to cause no or at least no significant harm.

Further, the laser system according to the present invention can be enhanced in that the laser system comprises a shielding aperture with a shielding aperture opening, and wherein the shielding aperture is arranged with its shielding aperture opening at the focal volume. In particular in evaporation systems in which the laser system according to the present invention is used to evaporate and/or sublimate material of the target, some of this evaporated and/or sublimated material moves in the direction towards the chamber window. By arranging the shielding aperture with its shielding aperture opening around the focal volume, an optimized shielding of the chamber window against deposition of target material evaporated and/or sublimated by the impinging laser beam can be provided. Maintenance intervals for the chamber window can thereby be extended.

According to a third aspect of the invention, the above object is also satisfied by an evaporation system, the evaporation system comprising a target located in a reaction chamber and at least one laser system for heating a surface of the target. The evaporation system according to the present invention is characterized in that the evaporation system comprises a control system adapted to apply the method according to the first aspect of the invention for running the at least one laser system and/or the at least one laser system is constructed according to the second aspect of the invention.

The evaporation system according to the invention can comprise a control system adapted to apply the method according to the first aspect of the invention for running the at least one laser system. All features and advantages described above with respect to a method according to the first aspect of the invention can hence also be provided by the evaporation system according to the third aspect of the invention carrying out the method according to the first aspect of the invention.

Alternatively, or additionally, the evaporation system according to the invention can comprise a laser system according to the second aspect of the invention. All features and advantages described above with respect to a laser system according to the second aspect of the invention can hence also be provided by the evaporation system according to the third aspect of the invention comprising the laser system according to the second aspect of the invention.

Further, the evaporation system according to the present invention can include a target that comprises material to be evaporated and/or sublimated during operation of the evaporation system. In other words, the method according to the first aspect of the invention and/or the laser system according to the second aspect present invention can be used in the evaporation system according to the third aspect of the present invention for evaporating and/or sublimating the material of the target. By using the method according to the first aspect of the invention and/or the laser system according to the second aspect of the present invention, and especially the laser beam provided with its ring-shaped intensity profile, a particularly uniform evaporation and/or sublimation of the material of the target can be provided, especially also towards the rim and/or edges and/or corners of the target surface.

Additionally or alternatively, the evaporation system according to the present invention can comprise that the target comprises material to be coated during operation of the evaporation system. In other words, the method according to the first aspect of the invention and/or the laser system according to the second aspect present invention can also be used in the evaporation system for heating the target, onto which evaporated and/or sublimated material should be deposited. By using the method according to the first aspect of the invention and/or the laser system according to the second aspect of the present invention, a particularly uniform temperature of the material of the target can be provided, especially also towards the rim and/or edges and/or corners of the target surface resulting in an especially uniform deposition environment for the materials to be deposited. In summary, this leads to an especially uniform coating of the target surface.

Please note that for using the laser system according to the second aspect of the present invention for both heating the target material to be evaporated and the target material to be coated, respectively, in most of the cases preferably two separate entities of laser systems according to the second aspect of the present invention are used.

The present invention is further described hereinafter with reference to illustrated embodiments shown in the accompanying drawings. There is shown:

FIG. 1 A laser system according to the state of the art,

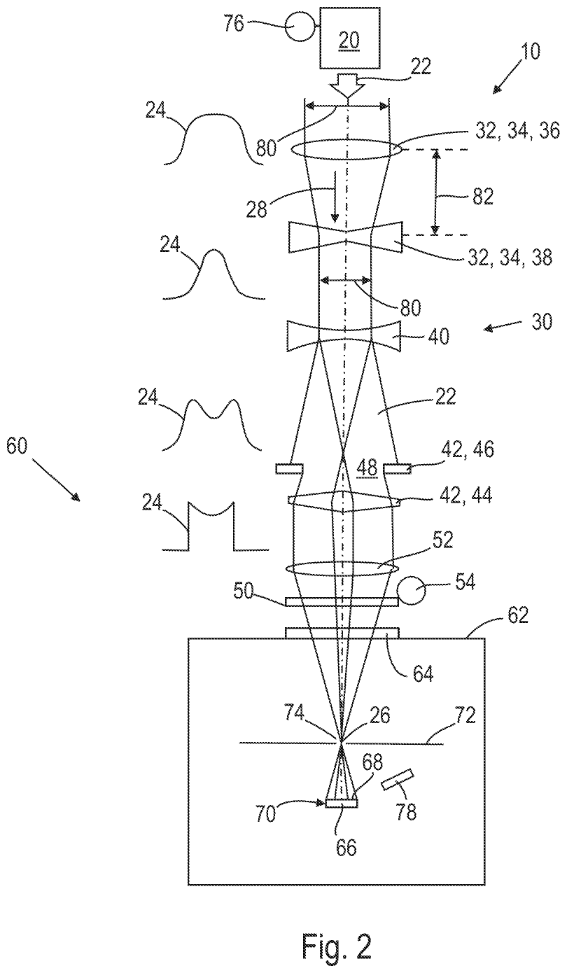

FIG. 2 An evaporation system according to the invention, and

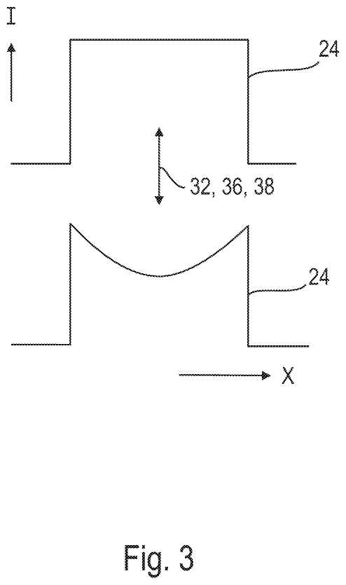

FIG. 3 Intensity profiles providable by the laser system according to the present invention.

FIG. 2 shows the evaporation system 60 according to the present invention which comprises the laser system 10 according to the present invention. The evaporation system 60 further comprises a reaction chamber 62, in which a target 66 is arranged. The surface 68 of the target 66 is to be heated by the laser system 10 described in the following. The heating of the target 66 by the laser system 10 can be used for either evaporation or coating of the target 66, respectively. The laser beam 22 provided by the laser light source 20 preferably is rotationally symmetric. It is further preferred that said rotational symmetry of the intensity profile 24 is preserved or alternatively actually provided for the first time by the beam shaping system 30 of the laser system 10 according to the present invention.

The evaporation system 60 is capable to carry out the method according to the present invention. In particular, the evaporation system 60 comprises a control system 76 for carrying out or at least controlling the execution of the respective steps of the method according to the present invention. In the following, the method according to the present invention will be described alongside the description of the evaporation system 60 and the laser system 10, respectively.

The main part of the laser system 10 is the beam shaping system 30. The main parts of this beam shaping system 30 are a beam telescope 32, a first generalized axicon 40 and an optical assembly 42 comprising a second generalized axicon 44 and a clipping aperture 46. In the depicted embodiment of the laser system 10 according to the present invention, the clipping aperture 46 is arranged along the path of the laser beam 22 before the second axicon 44. In other words, the clipping aperture 46 is placed in between the two axicons 40, 44. In an alternative embodiment, the clipping aperture 46 can also be arranged after the second axicon 44 (not shown).

Further elements of the beam shaping system 30 are a focusing element 52 and an additional deflection element 50. The depicted embodiment of the laser system 10 follows the deflection of the general propagation direction 28 of the laser beam 22 at the deflection element 50 and hence a change in the propagation direction 28 is not visible.

In the depicted embodiment, the shaping elements 32, 40, 42, 44, 46, 52 are depicted as separated entities. According to another embodiment of the laser system 10 of the present invention, at least two consecutively arranged shaping elements 32, 40, 42, 44, 46, 52 of the beam shaping system 30 can be integrated into a combined shaping element 32, 40, 44, 46, 52, in any suitable order.

A laser light source 20 of the laser system 10 provides an at least essentially parallel laser beam 22 with an intensity profile 24 that often has the form of a Gaussian distribution, which is indicated next to the focusing lens 36, which is the first optical element 34 of the beam telescope 32 of the beam shaping system 30. Alternatively, also at least essentially uniform intensity profiles 24 such as top-hat intensity profile 24 (not shown) are possible.

Without altering the laser beam 22 any further, this usually Gaussian intensity profile 24 would result in a non-uniform temperature profile of the surface 68 of the target 66, in particular in a temperature at the surface 68 of the target 66 decreasing towards an outer rim 70 and/or edges and/or corners of the surface 68 of the target 66. Said temperature profile is determined as temperature information in step a) of the method according to the present invention, for instance by a direct temperature measurement provided by a temperature sensor 78 and/or indirectly by measuring the present intensity profile 24 by a suitable sensor element 54 as described below. The analysis of the respective measurements and the actual determination of the temperature information can be provided by the control system 76 of the evaporation system 60.

The determined temperature information is consecutively used in the next step b) of the method according to the present invention to determine an adapted intensity profile 24. This step b) can preferably be executed by the control system 76 of the evaporation system 10. The newly determined intensity profile 24 is chosen such as to compensate the aforementioned temperature profile and to provide a uniform temperature of the surface 68 of the target 66 when irradiated with the laser beam 22 with the adapted intensity profile 24. In particular, repetitions of steps a) and b) allow a closed-loop control.

The actual shaping of the intensity profile 24 by the beam shaping system 30 according to step c) of the method according to the present invention will be described in the following.

The aforementioned beam telescope 32 in the depicted embodiment is formed by a matched pair of optical elements 34, in particular a focusing lens 36 and a defocusing lens 38. The lenses 36, 38 comprise matched focal lengths in such that the respective focal points of the lenses 36, 38 are identical or at least essentially identical. Hence the parallel laser beam 22 focused by the focusing lens 36 onto the defocusing lens 38 is transferred back into a parallel laser beam 22 by the defocusing lens 38.

Please note that the depicted embodiment of the laser system 10 according to the present invention comprises a beam telescope 32, in which along the path of the laser beam 22 the first optical element 34 is a focusing optical element 34, namely focusing lens 36, and the second optical element 34 is a defocusing optical element 34, namely defocusing lens 38. This arrangement results in a reduction of the diameter 80 of the laser beam 22. In an alternative embodiment of the beam telescope 20, the order of the optical elements 34 can be reversed, resulting in an enlargement of the diameter 80 of the laser beam 22.

In particular, said transformation of the laser beam 22 back to a parallel alignment can be provided independently from a distance 82 of the two lenses 36, 38, as long as the aforementioned matching of the respective focal lengths of the lenses 36, 38 is preserved. In other words, the diameter 80 of the resulting parallel laser beam 22 after the defocusing lens 38 changes dependent on the actual focal lengths of the two lenses 36, 38.

Hence, by continuously adjusting the matched focal lengths of the two lenses 36, 38, also continuous variation of the diameter 80 of the laser beam 22 can be provided. This change of the diameter 80 of the laser beam 22 is again indicated next to the defocusing lens 38 on the left-hand side of FIG. 2.

As an alternative to the pair of matched lenses 36, 38 described above, also a matched pair of preferably adaptive mirrors, a focusing mirror and a defocusing mirror (both not depicted), can be used as optical elements 34 of the beam telescope 32. The matched adaptive mirrors comprise variable focal lengths, preferably continuously variable focal lengths, and can also provide parallel laser beam 22 with a continuously adjustable diameter 80. For providing an enlarged or a reduced diameter 80 of the laser beam 22, the order of the two mirrors along the path of the laser beam 22 can be accordingly chosen as described above. Providing adaptive mirrors allows to actively adjust the actual diameter 80 of the laser beam 22 provided by the respective beam telescope 20.

Along the path of the laser beam 22 follows the first generalized axicon 40 which defocusses the parallel laser beam 22 and additionally transfers the usually at least essentially Gaussian intensity profile 24 of the laser beam 22 into ring-shaped intensity profile 24 shown on the left-hand side of FIG. 2 after the first generalized axicon 40.

In the depicted embodiment, after the first generalized axicon 40, an optical assembly 42 comprising a clipping aperture 46 and a second generalized axicon 44 is arranged. In the depicted embodiment of the laser system 10, the clipping aperture 46 with a clipping aperture opening 48 is arranged following the first axicon 40. This clipping aperture 46 clips outer parts of the ring-shaped intensity profile 24 of the laser beam 22 and hence defines the shape of the outer edge of intensity profile 24. Alternatively, the clipping aperture 46 can also be arranged after the second axicon 44 (not depicted).

After the clipping aperture 46 the second axicon 44 is arranged along the path of the laser beam 22. The two axicons 40, 44 are matched with respect to their focal lengths and hence the parallel laser beam 22 impinging on the first axicon 40 is again provided as parallel laser beam 22 after the second axicon 44. However, the ring shape intensity profile 24 stays preserved after the second axicon 44, as shown again on the left-hand side of FIG. 2. The first axicon 40 and also the following second axicon 44 can preferably be provided as strictly axicons, i.e. as conical lenses.

Essentially, after the optical assembly 42 and hence after the second axicon 44 and the clipping aperture 46, independent of the order of these shaping elements 44, 46, the shaping of intensity profile 24 and hence the beam shaping process according to step c) of the method according to the present invention is finished. In the following, step d) of the method according to the present invention and hence the provision of the laser beam 22 with the adapted intensity profile 24 for heating the surface 68 of the target 66 will be described.

As the last but one element, the beam shaping system 30 comprises a focusing element 52 for focusing the laser beam 22 onto the surface 68 of the target 66. In particular, the focal length of the focusing element 52 is chosen such that the clipping aperture opening 48 is projected onto a rim 70 of the surface 68 of the target 66. This ensures that the outer parts of the ring-shaped intensity profile 24, which comprise a higher energy density, impinge on the rim 70 of the surface 68 of the target 66, where higher radiative losses occur as described above with respect to FIG. 1. A compensation of this higher radiative losses can therefore be provided by the laser system 10 according to the present invention.

Preferably and as shown in the depicted embodiment, the focusing element 52 may focus the laser beam 22 onto a point-like focal volume 26 between the chamber window 64 and the target 66. This allows to arrange a shielding aperture 72 with a shielding aperture opening 74 at the focal volume 26 and hence effectively a shielding of the chamber window 64 from any material evaporated from the target 66 by the impinging laser beam 22.

As mentioned above, the deflection element 50 is arranged as last element of the beam shaping system 30 before the chamber window 64 of the reaction chamber 62. In other words, in this preferred embodiment the beam shaping system 30 is fully arranged outside of the reaction chamber 62, each element of the beam shaping system 30 is accessible without opening the reaction chamber 62. In other embodiments (not shown) some parts of the beam shaping system 30 can also be arranged within the reaction chamber 62.

In the shown embodiment of the laser system 10 according to the present invention, the deflection element 50 is sensed by a preferably position sensitive sensor element 54. This position sensitive sensor element 54 allows to measure the energy deposited into the deflection element 50 and/or light transmitted through the deflection element 50 during deflection of the laser beam 22. As a result, the ring-shaped intensity profile 24 of the laser beam 22 can be monitored, in particular in the above mentioned closed-loop control.

Additionally, the deflection element 50 can be provided as a distributed Bragg reflector. Such a distributed Bragg reflector can be chosen such that it allows a high, preferably an at least essentially complete, reflection of the impinging laser beam 22, whereas light with different wavelengths, such as for instance heat radiation originating from the heated surface 68 of the target 66, can pass through the distributed Bragg reflector. In this case, the position sensitive sensor element 54 can preferably be arranged on-axis with respect to the optical axis pointing to the target 66 and be provided sensitive to the heat radiation emitted by the surface 68 of the target 66. Hence, a direct measurement of the temperature distribution of the surface 68 of the target 66 and/or its spatial and/or temporal variation can be provided. As a result, the above mentioned closed-loop control can be enhanced further.

In FIG. 3 two intensity profiles 24 provided by the laser system 10 according to the present invention are shown. The upper image shows a top-hat intensity profile 24, the lower image a ring-shaped intensity profile 24. As described above with respect to FIG. 2, the beam shaping system 30 is able to continuously adjust the intensity profile 24, indicated in FIG. 3 by the double-headed arrow and the reference to the beam telescope 32 of the beam shaping system 30, in particular the reference to the variable focal lengths of the matched pair of the focusing lens 36 and the defocusing lens 38, such that the intensity profile 24 can actively be adjusted and varied, respectively, by the beam shaping system 30 from the top-hat intensity profile 24 to a ring-shaped intensity profile 24 suitable for heating the target 66 in the desired way.

### REFERENCES

10 laser system
20 laser light source
22 laser beam
24 intensity profile
26 focal volume
28 propagation direction
30 beam shaping system
32 beam telescope
34 optical element
36 focusing lens
38 defocusing lens
40 first generalized axicon
42 optical assembly
44 second generalized axicon
46 clipping aperture
48 clipping aperture opening
50 deflection element
52 focusing element
54 sensor element
60 evaporation system
62 reaction chamber
64 chamber window
66 target
68 surface
70 rim
72 shielding aperture
74 shielding aperture opening
76 control system
78 temperature sensor
80 diameter
82 distance
90 deviation (left)
92 deviation (right)

1-35. (canceled)

36. A method of running a laser system for providing a laser beam capable of heating a surface of a target located in a reaction chamber of an evaporation system, the laser system comprising a laser light source for providing an at least essentially parallel laser beam with an at least essentially centrally peaked intensity profile, comprising the steps of:
a) Determining a temperature information of the surface of the target,
b) Determining an adapted intensity profile for the laser beam with a lower center intensity based on the temperature information determined in step a),
c) Shaping the intensity profile of the laser beam based on the determination carried out in step b), and
d) Providing the laser beam with the adapted intensity profile shaped in step c) for heating the surface of the target located in the reaction chamber of the evaporation system.

37. The method according to claim 36,
wherein the determination of the temperature information in step a) includes at least one of the following:
Estimating the temperature information based on the intensity of the laser beam provided by the laser light source,
Estimating the temperature information based on measuring the temperature at the center of the surface of the target,
Estimating the temperature information based on measuring the temperature at the outer rim of the surface of the target, and/or
Estimating the temperature information based on measuring the temperature at the center, at the outer rim, and at least at one additional position of the surface of the target.

38. The method according to claim 37,
wherein the respective temperature of the surface of the target is measured with respect to the provided laser beam at the far side of the target opposite to the surface of the target heated by the laser beam.

39. The method according to claim 37,
wherein the respective temperature of the surface of the target is measured on-axis with the provided laser beam.

40. The method according to claim 36,
wherein the newly shaped intensity profile is rotationally symmetric.

41. A laser system for heating a surface of a target located in a reaction chamber of an evaporation system, the reaction chamber comprising a chamber window, and the laser system comprising a laser light source for providing an at least essentially parallel laser beam with an at least essentially centrally peaked intensity profile,
wherein the laser system comprises a beam shaping system configured to carry out at least step c) of the method according to claim 36.

42. The laser system according to claim 41,
wherein the beam shaping system comprises, along the path of the laser beam at least the following shaping elements:
a beam telescope for adjusting a diameter of the laser beam;
a generalized first axicon for transforming the parallel laser beam into a diverging laser beam with an at least partly ring-shaped intensity profile;
an optical assembly comprising as shaping elements a clipping aperture with a clipping aperture opening for clipping outer parts of the ring-shaped intensity profile of the laser beam and a generalized second axicon for compensating the divergence of the laser beam and transforming the divergent laser beam into a parallel laser beam; and
a focusing element for focusing the laser beam towards the surface of the target.

43. The laser system according to claim 42,
wherein within the optical assembly the clipping aperture is arranged upstream of the second axicon along the path of the laser beam.

44. The laser system according to claim 42,
wherein within the optical assembly the second axicon is arranged upstream of the clipping aperture along the path of the laser beam.

45. The laser system according to claim 42,
wherein at least two consecutively arranged shaping elements of the beam shaping system are integrated into a combined shaping element.

46. The laser system according to claim 41,
wherein at least some parts of the beam shaping system are arranged outside of the chamber window of the reaction chamber.

47. The laser system according to claim 46,
wherein said parts comprise at least some or all of the following components: the beam telescope, the first axicon, the optical assembly, the clipping aperture, and the second axicon.

48. The laser system according to claim 47,
wherein the focusing element is arranged outside of the chamber window of the reaction chamber.

49. The laser system according to claim 48,
wherein the second axicon and the focusing element are integrated into a freeform lens or a freeform mirror.

50. The laser system according to claim 49,
wherein the freeform mirror is an adaptive mirror with an actively adjustable focal length.

51. The laser system according to claim 42,
wherein the focusing element is arranged within the reaction chamber after the chamber window.

52. The laser system according to claim 42,
wherein the beam telescope comprises optical elements for a continuous adjustment of the diameter of the laser beam.

53. The laser system according to claim 52,
wherein the optical elements of the beam telescope comprise along the path of the laser beam a matched pair of a focusing optical element and a defocusing optical element.

54. The laser system according to claim 52,
wherein the optical elements of the beam telescope comprise along the path of the laser beam a matched pair of a defocusing optical element and a focusing optical element.

55. The laser system according to claim 53,
wherein the pair of optical elements are matched such that the pair of optical elements comprise respective positions along the path of the laser beam and respective focal lengths for providing at least essentially identical respective focal point positions of the pair of optical elements.

56. The laser system according to claim 55,
wherein the respective focal lengths of the optical elements along the path of the laser beam can be continuously adjusted.

57. The laser system according to claim 52,
wherein the optical elements of the beam telescope are a matched pair of at least essentially spherical lenses.

58. The laser system according to claim 52,
wherein the optical elements of the beam telescope are a matched pair of mirrors.

59. The laser system according to claim 42,
wherein the beam shaping system comprises a deflection element for changing the general propagation direction of the laser beam, wherein the deflection element is arranged along the path of the laser beam somewhere after the optical assembly.

60. The laser system according to claim 59,
wherein the deflection element is the last element of the beam shaping system arranged along the path of the laser beam before the chamber window.

61. The laser system according to claim 59,
wherein the deflection element is a distributed Bragg reflector.

62. The laser system according to claim 59,
wherein the laser system comprises sensor elements for measuring an amount of energy deposited into the deflection element and/or an amount of light transmitted through the deflection element during deflection of the laser beam.

63. The laser system according to claim 62,
wherein the sensor elements are position sensitive sensor elements for measuring the amount of energy deposited into the deflection element and/or the amount of light transmitted through the deflection element during deflection of the laser beam at two or more positions of the deflection element.

64. The laser system according to claim 62,
wherein the deflection element is a distributed Bragg reflector and wherein the sensor elements are arranged on-axis with respect to the optical axis of the laser beam pointing to the target on the far side of the distributed Bragg reflector with respect to the impinging laser beam for measuring heat radiation emitted by the surface of the target.

65. The laser system according to claim 42,
wherein the focusing element comprises a focal length such that the clipping aperture opening is projected onto an outer rim and/or onto edges and/or onto corners of the surface of the target.

66. The laser system according to claim 42,
wherein the focusing element focuses the laser beam on a point-like focal volume located within the reaction chamber between the chamber window and the target.

67. The laser system according to claim 66,
wherein the laser system comprises a shielding aperture with a shielding aperture opening, and wherein the shielding aperture is arranged with its shielding aperture opening at the focal volume.

68. An evaporation system, the evaporation system comprising a target located in a reaction chamber and at least one laser system for heating a surface of the target,
wherein the evaporation system comprises a control system adapted to apply the method according to claim 36, for running the at least one laser system and/or the at least one laser system is constructed for heating a surface of a target located in a reaction chamber of an evaporation system, the reaction chamber comprising a chamber window, and the laser system comprising a laser light source for providing an at least essentially parallel laser beam with an at least essentially centrally peaked intensity profile,
wherein the laser system comprises a beam shaping system configured to carry out at least step c) of the method according to claim 36.

69. The evaporation system of claim 68,
wherein the target comprises material to be evaporated and/or sublimated during operation of the evaporation system.

70. The evaporation system of claim 68,
wherein the target comprises material to be coated during operation of the evaporation system.
